(19) United States
(12) Patent Application Publication
(10) Pub. No.: US 2024/0250087 A1
(43) Pub. Date: Jul. 25, 2024

(54) SEMICONDUCTOR STRUCTURE, FORMATION METHOD, AND OPERATION METHOD

(71) Applicants: Semiconductor Manufacturing International (Shanghai) Corporation, Shanghai (CN); Semiconductor Manufacturing International (Beijing) Corporation, Beijing (CN)

(72) Inventor: Jisong JIN, Shanghai (CN)

(21) Appl. No.: 18/562,559

(22) PCT Filed: May 19, 2021
(86) PCT No.: PCT/CN2021/094532

§ 371 Date: Nov. 20, 2023

(51) Int. Cl. H01L 27/092; H01L 21/8238

(52) U.S. Cl. CPC H01L 27/0924; H01L 21/823821; H01L 21/823871; H01L 21/823878

(57) ABSTRACT

A semiconductor structure includes a substrate including a first region. The first region includes a plurality of first active regions arranged along a first direction and a first isolation region between the adjacent first active regions. The semiconductor structure also includes a plurality of first fins on the substrate, parallel to the first direction and arranged along a second direction. The second direction is perpendicular to the first direction. The first fins span the adjacent first active regions and the first isolation region between the first active regions. The semiconductor structure also includes a plurality of first gate structures in the first isolation region. The first gate structures span the first fins along the second direction. The semiconductor structure also includes a plurality of first electrical interconnection structures, electrically connected to the first gate structures.

### TECHNICAL FIELD

The present disclosure generally relates to the field of semiconductor manufacturing technology and, more particularly, relates to a semiconductor structure and a formation method thereof and an operation method thereof.

### BACKGROUND

As the integration level of semiconductor devices increases, critical dimensions of transistors may continuously decrease. However, with drastic reduction in transistor sizes, the thickness of the first dielectric layer of the gate and the operation voltage may not be changed accordingly. As such, it may become more difficult to suppress short channel effects, and channel leakage current of transistors may thus increase.

To electrically isolate adjacent transistors, an isolation layer may be formed at the boundary of the transistors. Simultaneously, to reduce the area of the isolation layer and to improve the integration level of the semiconductor structure formed, existing technology introduces single diffusion break (SDB) technology and double diffusion break (DDB) technology.

However, existing methods still have many problems in the process of forming semiconductor structures.

### SUMMARY

The present disclosure provides a semiconductor structure and a formation method thereof and an operation method thereof. The performance of the semiconductor structure may be improved, and the integration level of the semiconductor structure formed may be improved.

To solve the above technical problems, the present disclosure provides a semiconductor structure. The semiconductor structure includes: a substrate, where the substrate includes a first region, and the first region includes a plurality of first active regions arranged along a first direction and a first isolation region located between adjacent first active regions of the plurality of first active regions; a plurality of first fins located over the substrate, where the plurality of first fins extends in parallel to the first direction and is arranged along a second direction, the second direction is perpendicular to the first direction, and the plurality of first fins spans the adjacent first active regions and the first isolation region between the adjacent first active regions; a plurality of first gate structures located over the first isolation region, where the plurality of first gate structures spans the plurality of first fins along the second direction; and a plurality of first electrical interconnection structures, where the plurality of first electrical interconnection structures is electrically connected to the plurality of first gate structures.

Optionally, the semiconductor structure also includes an isolation layer over the substrate. The isolation layer covers a part of sidewalls of the plurality of first fins, a top surface of the isolation layer is lower than a top surface of the plurality of first fins, a first gate structure of the plurality of first gate structures includes a first portion located on a surface of a first fin of the plurality of first fins and a second portion located on a surface of the isolation layer, and a first electrical interconnection structure of the plurality of first electrical interconnection structures is electrically connected to the second portion.

Optionally, the semiconductor structure also includes a first dielectric layer located over the substrate, where the first dielectric layer covers a sidewall of a first gate structure of the plurality of first gate structures.

Optionally, a first electrical interconnection structure of the plurality of first electrical interconnection structures includes a plurality of plugs located on a top surface of a second portion of the first gate structure, and an interconnection layer located over the plurality of plugs; and the plurality of plugs is separated from each other.

Optionally, a top surface of the first gate structure is lower than a top surface of the first dielectric layer, and a part of the plurality of plugs is located in the first dielectric layer.

Optionally, a first electrical interconnection structure of the plurality of first electrical interconnection structures includes plugs located over a top surface of adjacent first gate structures of the plurality of first gate structures and an interconnection layer located over the plugs; and the plugs are also located over a surface of the first dielectric layer between the adjacent first gate structures.

Optionally, a top surface of the first gate structure is lower than a top surface of the first dielectric layer, and a part of the plugs is also located in the first dielectric layer.

Optionally, a second gate structure located over first active regions of the plurality of the first active regions, where the second gate structure spans the plurality of first fins along the second direction.

Optionally, the substrate also includes: a second region; a plurality of second fins located over the second region, where the plurality of second fins extends in parallel to the first direction and is arranged along the second direction; and a plurality of third gate structures located over the second region, where the plurality of third gate structure spans the plurality of second fins, and a part of the plurality of third gate structures is connected to the second gate structure.

Optionally, the substrate also includes a second region. The second region includes: a plurality of second active regions arranged along the first direction and a second isolation region located between adjacent second active regions of the plurality of second active regions; a plurality of third fins on the second region, where the plurality of third fins extends in parallel to the first direction and is arranged along the second direction, and a third fin of the plurality of third fins spans the adjacent second active regions and the second isolation region between the adjacent second active regions; a plurality of fourth gate structures located over the second isolation region, where the plurality of fourth gate structures spans the third fin along the second direction, and the plurality of fourth gate structure is spaced apart from a first gate structure of the plurality of first gate structures in the second direction; and a plurality of second electrical interconnection structures, where the plurality of second electrical interconnection structures is electrically connected to a fourth gate structures of the plurality of fourth gate structures.

Optionally, the semiconductor structure also includes a fifth gate structure located over a second active region of the plurality of second active regions, where the fifth gate structure spans the third fin along the second direction, and the fifth gate structure is connected to the second gate structure.

Optionally, the semiconductor structure also includes: a first source/drain doped layer in a first fin of the plurality of first fins located on two sides of each of the plurality of first gate structures and on two sides of the second gate structure, where the first source/drain doped layer contains first source/drain ions; and a second source/drain doped layer in a second fin of the plurality of second fins located on two sides of each of the plurality of third gate structures, where the second source/drain doped layer contains second source/drain ions.

Optionally, conductivity types of the first source/drain ions and the second source/drain ions are different; the first source/drain ions include N-type ions or P-type ions; and the second source/drain ions include P-type ions or N-type ions.

Optionally, the semiconductor structure also includes a first conductive layer over the first source/drain doped layer and a second conductive layer over the second source/drain doped layer.

Optionally, the semiconductor structure also includes: a first source/drain doped layer in a first fin of the plurality of first fins located on two sides of each of the plurality of first gate structures and on two sides of the second gate structure, where the first source/drain doped layer contains first source/drain ions; and a third source/drain doped layer in the third fin located on two sides of each of the plurality of fourth gate structures and on two sides of the fifth gate structure, where the third source/drain doped layer contains third source/drain ions.

Optionally, conductivity types of the first source/drain ions and the third source/drain ions are different; the first source/drain ions include N-type ions or P-type ions; and the third source/drain ions include P-type ions or N-type ions.

Optionally, the semiconductor structure also includes a first conductive layer located on the first source/drain doped layer and a third conductive layer located on the third source/drain doped layer.

Correspondingly, the present disclosure also provides a method for forming a semiconductor structure. The method includes: providing a substrate, where the substrate includes a first region, the first region includes a plurality of first active regions arranged along a first direction and a first isolation region located between adjacent first active regions of the plurality of first active regions; forming a plurality of first fins over the first region, where the plurality of first fins extends in parallel to the first direction and is arranged along a second direction, the second direction is perpendicular to the first direction, and the plurality of first fins spans the adjacent first active regions and the first isolation region between the adjacent first active regions; forming a plurality of first gate structures over the first isolation region, where the plurality of first gate structures spans the plurality of first fins along the second direction; and forming a plurality of first electrical interconnection structures, where the plurality of first electrical interconnection structures is electrically connected to the plurality of first gate structures.

Optionally, after forming the plurality of first fins, the method also includes forming an isolation layer over the substrate, where the isolation layer covers a part of sidewalls of the plurality of first fins, and a top surface of the isolation layer is lower than a top surface of the plurality of first fins.

Optionally, after forming the plurality of first fins and before forming the plurality of first gate structures, the method also includes: forming a plurality of first dummy gate structures over the first isolation region, where the plurality of first dummy gate structures spans the plurality of first fins; and forming a first dielectric layer over the substrate, where the first dielectric layer covers sidewalls of the plurality of first dummy gate structure, and exposes a top surface of the plurality of first dummy gate structures.

Optionally, a process of forming the plurality of first gate structures includes: removing the plurality of first dummy gate structures to form a plurality of first gate openings in the first dielectric layer; and forming the plurality of first gate structures in the plurality of first gate openings.

Optionally, after forming the plurality of first gate structures, the method also includes forming a second dielectric layer on the first dielectric layer, where the plurality of first electrical interconnection structures is located in the second dielectric layer.

Optionally, a process of forming the plurality of first electrical interconnection structures includes: forming a plurality of contact holes separated from each other in the second dielectric layer, where bottoms of the plurality of contact holes respectively expose top surfaces of the plurality of first gate structures; forming a plug in each of the plurality of contact holes; and forming an interconnection layer over the plug.

Optionally, before forming the plurality of contact holes, the method also includes etching back a part of the plurality of first gate structures until a top surface of the plurality of first gate structures is lower than a top surface of the first dielectric layer.

Optionally, a process of forming the plurality of first electrical interconnection structures includes: forming a contact hole in the second dielectric layer, where a bottom of the contact hole exposes a plurality of adjacent first gate structures of the plurality of first gate structures and a top surface of the first dielectric layer between the plurality of first gate structures; forming a plug in the contact hole; and forming an interconnection layer over the plug.

Optionally, before forming the contact hole, the method also includes etching back a part of the plurality of first gate structures until a top surface of the plurality of first gate structures is lower than a top surface of the first dielectric layer.

Correspondingly, the present disclosure also provides an operation method of a semiconductor structure. The semiconductor structure includes a substrate, where the substrate includes a first region, and the first region includes a plurality of first active regions arranged along a first direction and a first isolation region located between adjacent first active regions of the plurality of first active regions; a plurality of first fins located over the substrate, where the plurality of first fins extends in parallel to the first direction and is arranged along a second direction, the second direction is perpendicular to the first direction, and the plurality of first fins spans the adjacent first active regions and the first isolation region between the adjacent first active regions; a plurality of first gate structures located over the first isolation region, where the plurality of first gate structures spans the plurality of first fins along the second direction; and a plurality of first electrical interconnection structures, where the plurality of first electrical interconnection structures is electrically connected to the plurality of first gate structures. The operation method includes applying a voltage to the plurality of first electrical interconnection structures to turn off a channel region at a bottom of the plurality of first gate structure.

Optionally, the semiconductor structure also includes a first source/drain doped layer in a first fin of the plurality of first fins located on two sides of each of the plurality of first gate structures, where the first source/drain doped layer contains first source/drain ions. The operation method also includes, when the first source/drain ions are N-type ions, applying a negative voltage to the plurality of first electrical interconnection structures, and when the first source/drain ions are P-type ions, applying a positive voltage to the plurality of first electrical interconnection structures.

Compared with the existing technology, the technical solution of the present disclosure has the following advantages.

The semiconductor structure provided by the present disclosure includes a plurality of first active regions and a first isolation region between the adjacent first active regions, first fins spanning the adjacent first active regions and the first isolation region between the first active regions, a plurality of first gate structures on the first isolation region, where the plurality of first gate structures spans the first fins, and a plurality of first electrical interconnection structures electrically connected to the first gate structures. The first electrical interconnection structure provides an off signal to the first gate structure, such that the channel in the first fin of the first isolation region is in an off state, making the first gate structure in an ineffective state, thereby electrically isolating the first active regions on two sides of the first isolation region. It is not necessary to remove the first gate structure to form an isolation structure to achieve the isolation effect, and effective electrical isolation may be realized even when the semiconductor structure has a high integration level. Moreover, the first fin spans the adjacent first active region and the first isolation region between the first active regions, without cutting off the first isolation region of the first fin. Accordingly, the layout-dependent effect caused by the cut-off structure of the first fin may be avoided, and performance of the semiconductor structure may be improved.

In the formation method provided by the present disclosure, first fins are formed spanning the first active regions and the first isolation region between the adjacent first active regions, a plurality of first gate structures across the first fin is formed on the first isolation region, and a plurality of first electrical interconnection structures is formed on the first gate structure. By providing an off signal to the first gate structure through the first electrical interconnection structure, the channel region at the bottom of the first gate structure may be made to be in an off state, thereby realizing electrical isolation between the first active regions on two sides of the first isolation region. It is not necessary to remove the first gate structure to form an isolation structure to achieve the isolation effect, and effective electrical isolation may be achieved even when the semiconductor structure has a high integration level. Moreover, the first fin spans the adjacent first active region and the first isolation region between the first active regions. It is not necessary to cut off the first isolation region of the first fin. Accordingly, the layout-dependent effect caused by the cut-off structure of the first fin may be avoided, and performance of the semiconductor structure may be improved.

In the operation method provided by the present disclosure, by applying a voltage to the first electrical interconnection structure, the first electrical interconnection structure may provide an off signal to the first gate structure, such that the channel region at the bottom of the first gate structure is in an off state, thereby realizing electrical isolation between the first active regions on two sides of the first isolation region. It is not necessary to remove the first gate structure to form an isolation structure to achieve the isolation effect. As such, effective electrical isolation may be achieved even when the semiconductor structure has a high integration level. Moreover, the first fin spans the adjacent first active regions and the first isolation region between the first active regions. There is no need to cut off the first isolation region of the first fin. Accordingly, the layout-dependent effect caused by the cut-off structure of the first fin may be avoided, and performance of the semiconductor structure may be improved.

### BRIEF DESCRIPTION OF THE DRAWINGS

FIGS. 1-2 illustrate structural schematics of a semiconductor structure.

FIGS. 3-25 illustrate structural schematics corresponding to certain stages of a process of forming a semiconductor structure, consistent with the disclosed embodiments of the present disclosure.

FIGS. 26-32 illustrate structural schematics corresponding to certain stages of another process of forming a semiconductor structure, consistent with the disclosed embodiments of the present disclosure.

### DETAILED DESCRIPTION

It may be seen from the background that, the DDB or SDB technology is often used in existing technology to realize electrical isolation between adjacent transistors, but problems may still exist. Specific explanations will be given in conjunction with accompanying drawings.

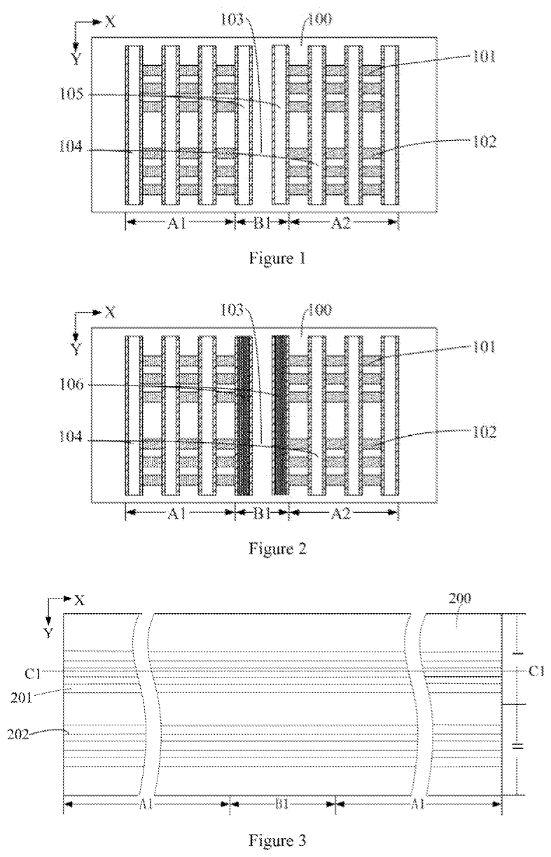

FIGS. 1-2 illustrate structural schematics of a semiconductor structure.

Referring to FIG. 1, the semiconductor structure includes: a substrate 100, where the substrate 100 includes a first active region A1, an isolation region B1 and a second active region A2 arranged along a first direction X, and the isolation region B1 is located between the first active region A1 and the second active region A2; a plurality of first fins 101 and a plurality of second fins 102 located on the substrate 100, where the plurality of first fins 101 and the plurality of second fins 102 are arranged along a second direction Y, the first direction X is perpendicular to the second direction Y, the plurality of first fins 101 and the plurality of second fins 102 have an isolation opening 103 inside, the isolation opening 103 runs through the first fins 101 and the second fins 102 along the second direction Y, and the isolation opening 103 is located on the isolation region B1; a plurality of first gate structures 104 located on the first active region A1 and the second active region A2, and a plurality of second gate structures 105 located in the isolation region B1, where the plurality of first gate structures 104 and the plurality of second gate structures 105 span the first fins 101 and the second fins 102.

Referring to FIG. 2, in the above semiconductor structure, to realize electrical isolation between the first active region A1 and the second active region A2, the second gate structure 105 on the isolation region B1 may be also removed to form a gate opening. An isolation structure 106 may then be formed in the gate opening, and isolation may be realized through the isolation structure 106.

In the above semiconductor structure, on the one hand, due to the isolation opening 103 in the first fin 101 and the second fin 102, in a process of manufacturing miniaturized semiconductor devices, the isolation opening 103 may affect the layout of surrounding devices. That is, a layout dependence effect (LDE) may appear, and the performance of the semiconductor structure may thus be affected. On the other hand, each isolation region may form a gate structure, and the gate structure may be removed to form an isolation structure. As such, the integration level of the semiconductor structure may be decreased.

To solve the above problems, the present disclosure provides a semiconductor structure. A first electrical interconnection structure is connected to a plurality of first gate structures on the first isolation region. By applying a voltage to the first electrical interconnection structure, an off signal may be provided to the first gate structure, such that the channel region at the bottom of the first gate structure may be in an off state. As such, the first gate structure may become ineffective, and electrical isolation of the first active region on two sides of the first isolation region may thus be realized. On the one hand, there is no need to remove the first gate structure to form the isolation structure, and the integration level of the semiconductor structure may be improved. On the other hand, the first fin does not need to be cut off in the first isolation region. Accordingly, the layout dependence effect caused by the cut-off structure of the first fin may be avoided, and the performance of the semiconductor structure may be improved.

To make the above objects, features and beneficial effects of the present disclosure obvious and understandable, specific embodiments of the present disclosure will be described in detail below in conjunction with the accompanying drawings.

FIGS. 3-25 illustrate structural schematics corresponding to certain stages of a process of forming a semiconductor structure, consistent with the disclosed embodiments of the present disclosure.

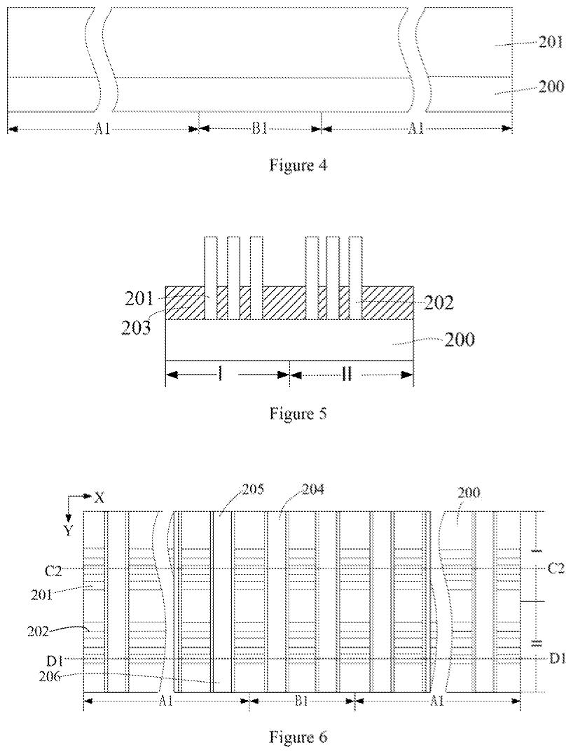

FIG. 3 is a top view of a semiconductor structure, and FIG. 4 is a cross-sectional structural schematic of FIG. 3 along the C1-C1 direction. Referring to FIGS. 3 and 4, the process includes providing a substrate 200. The substrate 200 includes a first region I. The first region I includes a plurality of first active regions A1 arranged along a first direction X and a first isolation region B1 located between adjacent first active regions A1.

In one embodiment, the substrate 200 may also include a second region II. The first zone I and the second zone II are arranged along a second direction Y, and the second direction Y is perpendicular to the first direction X. In some other embodiments, the substrate 200 may not include the second region.

In one embodiment, the second region II may not include an isolation region. In another embodiment, the second region II includes a plurality of second active regions arranged along the first direction X and a second isolation region located between the adjacent second active regions.

In one embodiment, the material of the substrate 200 is silicon. In some other embodiments, the material of the substrate may be germanium, silicon germanium, silicon carbide, gallium arsenide or gallium indium.

A plurality of first fins 201 may be formed on the first region I. The first fins 201 are parallel to the first direction X and are arranged along the second direction Y. The first fin 201 spans the adjacent first active regions A1 and the first isolation region B1 between the first active regions A1.

In one embodiment, the process also includes forming a plurality of second fins 202 on the second region II. The second fins 202 are parallel to the first direction X and are arranged along the second direction Y.

In one embodiment, the material of the first fins 201 and the second fins 202 is silicon. In some other embodiments, the material of the first fins and the second fins may be germanium, silicon germanium, silicon carbide, gallium arsenide or gallium indium.

FIG. 5 is a cross-sectional schematic along the second direction Y. Referring to FIG. 5, the process also includes, after the first fins 201 are formed, forming an isolation layer 203 on the substrate 200. The isolation layer 203 covers part of sidewalls of the first fins 201 and the second fins 202. The top surface of the isolation layer 203 is lower than the top surfaces of the first fins 201 and the second fins 202.

In one embodiment, a method for forming the isolation layer 203 includes: forming an initial isolation layer (not shown) on the substrate 200; removing part of the initial isolation layer by etching to form the isolation layer 203. The top surface of the isolation layer 203 is lower than the top surfaces of the first fins 201 and the second fins 202.

The material of the isolation layer 203 is an insulating material. The insulating material may include silicon oxide or silicon oxynitride. In one embodiment, the material of the isolation layer 203 is silicon oxide.

After forming the isolation layer 203, the process also includes: forming a plurality of first gate structures on the first isolation region B1, where the first gate structures spans the first fins 201 along the second direction Y; forming a second gate structure on the first active region A1, where the second gate structure spans the first fin 201 along the second direction Y; forming a third gate structure on the second region II, where the third gate structure spans the second fin 202 along the second direction, and part of the third gate structure is connected to the second gate structure; and forming a first dielectric layer on the substrate 200, where the first dielectric layer covers the sidewall of the first gate structure. Specific forming processes are described below.

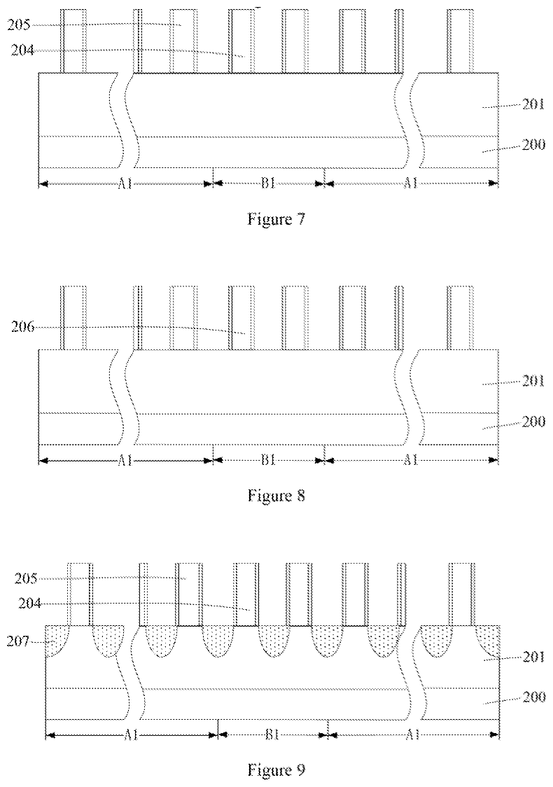

FIG. 6 is a top view of a semiconductor structure. FIG. 7 is a cross-sectional structural schematic of FIG. 6 along the C2-C2 direction, and FIG. 8 is a cross-sectional structural schematic of FIG. 6 along the D1-D2 direction. Referring to FIGS. 6-8, a plurality of first dummy gate structures 204 may be formed on the first isolation region B1, and the first dummy gate structures 204 span the first fins 201 on the first isolation region B1.

In one embodiment, the first dummy gate structure 204 includes a first portion located on the surface of the first fin 201 and a second portion located on the isolation layer 203.

In one embodiment, the process also includes: forming a plurality of second dummy gate structures 205 on the first active region A1, where the second dummy gate structures 205 spans the first fins 201 on the first active region A1; forming a third dummy gate structure 206 on the second region II, where the third dummy gate structure 206 spans the second fins 202. A part of the third dummy gate structures 206 is connected to the second dummy gate structure 205, and a part of the third dummy gate structures 206 is connected to the first dummy gate structure 204.

In one embodiment, the first dummy gate structures 204, the second dummy gate structures 205 and the third dummy gate structures 206 may be formed simultaneously.

In one embodiment, a method for forming the first dummy gate structure 204 includes: forming a first dummy gate dielectric layer (not shown) on the isolation layer 203; forming a first dummy gate layer (not marked) on the first dummy gate dielectric layer; and forming a first spacer (not marked) on sidewalls of the first dummy gate layer and the first dummy gate dielectric layer.

In one embodiment, the material of the first dummy gate dielectric layer is silicon oxide. In some other embodiments, the material of the first dummy gate dielectric layer may be silicon oxynitride.

In one embodiment, the material of the first dummy gate layer is polysilicon.

In one embodiment, the method for forming the second dummy gate structure 205 includes: forming a second dummy gate dielectric layer (not shown) on the isolation layer 203; forming a second dummy gate layer (not marked) on the second dummy gate dielectric layer; and forming a second spacer (not marked) on the sidewalls of the second dummy gate layer and the second dummy gate dielectric layer.

In one embodiment, the material of the second dummy gate dielectric layer may be same as the material of the first dummy gate dielectric layer, and the material of the second dummy gate layer may be same as the material of the first dummy gate layer.

In one embodiment, the method for forming the third dummy gate structure 206 includes: forming a third dummy gate dielectric layer (not shown) on the isolation layer 203; forming a third dummy gate layer (not marked) on the third dummy gate dielectric layer; and forming a third spacer (not marked) on the sidewalls of the third dummy gate layer and the third dummy gate dielectric layer.

In one embodiment, the material of the third dummy gate dielectric layer is same as the material of the first dummy gate dielectric layer, and the material of the third dummy gate layer is also same as the material of the first dummy gate layer.

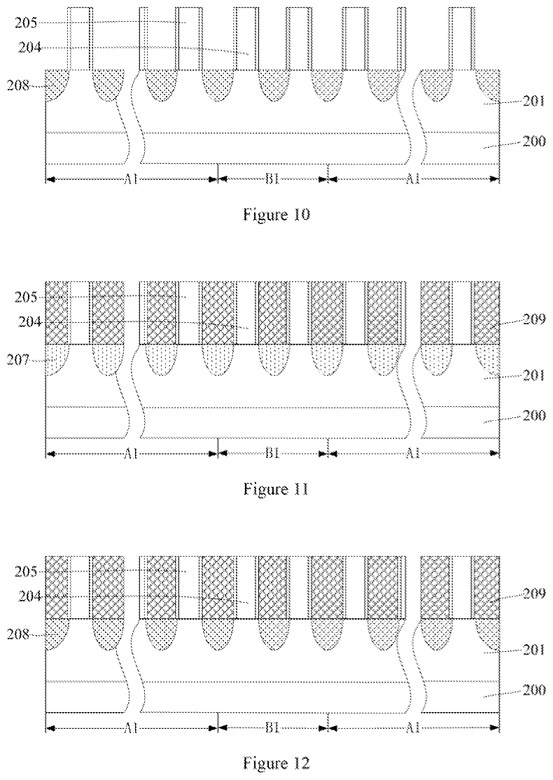

Cutting directions of FIG. 9 and FIG. 7 are consistent, and cutting directions of FIG. 10 and FIG. 8 are consistent. Referring to FIGS. 9 and 10, the process also includes: etching the first fins 201 by using the first dummy gate structure 204 and the second dummy gate structure 205 as a mask to form a plurality of first source/drain openings in the first fins 201 (not marked); etching the second fins 202 by using the third dummy gate structure 206 as a mask to form a plurality of second source/drain openings (not marked) in the second fins 202; forming a first source/drain doped layer 207 in the first source/drain opening; and forming a second source/drain doped layer 208 in the second source/drain opening.

In one embodiment, a method for forming the first source/drain doped layer 207 in the first source/drain opening includes: forming a first epitaxial layer (not marked) in the first source/drain opening by using an epitaxial growth process; and doping first source/drain ions into the first epitaxial layer to form the first source/drain doped layer 207 by performing in-situ doping on the first epitaxial layer during the epitaxial growth process.

In one embodiment, a method for forming the second source/drain doped layer 208 in the second source/drain opening includes: forming a second epitaxial layer (not marked) in the second source/drain opening by using an epitaxial growth process; doping second source/drain ions into the second epitaxial layer to form the second source/drain doped layer 208, by performing in-situ doping on the second epitaxial layer during the epitaxial growth process.

In one embodiment, the electrical types of the first source/drain ions and the second source/drain ions may be different. The first source/drain ions may be P-type ions, and the second source/drain ions may be N-type ions. In some other embodiments, the first source/drain ions may be N-type ions, and the second source/drain ions may be P-type ions.

The cutting directions of FIG. 11 and FIG. 9 are consistent, and the cutting directions of FIG. 12 and FIG. 10 are consistent. Referring to FIGS. 11 and 12, the process also includes: after the first source/drain doped layer 207 and the second source/drain doped layer 208 are formed, forming a first dielectric layer 209 on the substrate 200. The first dielectric layer 209 covers sidewalls of the first dummy gate structure 20, the second dummy gate structure 206 and the third dummy gate structure 206.

In one embodiment, a method for forming the first dielectric layer 209 includes: forming a first initial dielectric layer (not shown) on the substrate 200, where the first initial dielectric layer covers the first source/drain doped layer 207, the second source/drain doped layer 208, the first dummy gate structure 204, the second dummy gate structure 205 and the third dummy gate structure 206; forming the first dielectric layer 209 by performing a planarization process on the first initial dielectric layer until the top surfaces of the first dummy gate structure 204, the second dummy gate structure 205 and the third dummy gate structure 206 are exposed.

In one embodiment, the material of the first dielectric layer 209 is silicon oxide. In some other embodiments, the material of the first dielectric layer may be a low-K dielectric material (a low-K dielectric material refers to a dielectric material with a relative permittivity lower than 3.9) or an ultra-low-K dielectric material (an ultra-low-K dielectric material refers to a dielectric material with a relative permittivity lower than 2.5).

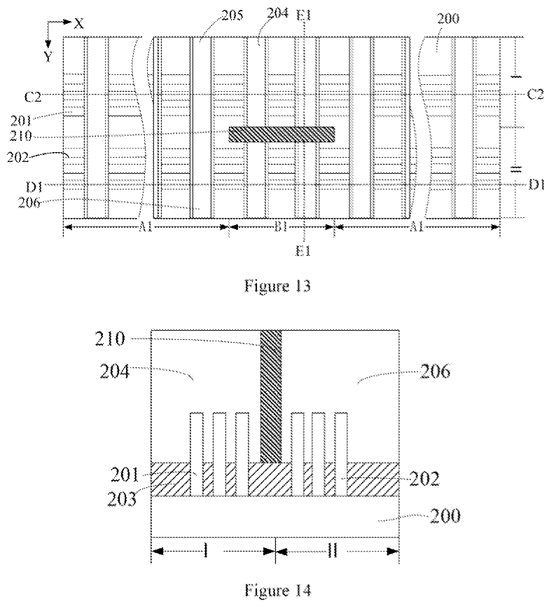

FIG. 13 is a top view of the semiconductor structure, and FIG. 14 is a cross-sectional structural schematic of FIG. 13 along the E1-E1 direction. Referring to FIGS. 13, and 14, the process also includes forming a gate isolation structure 210 between the first dummy gate structure 204 and the third dummy gate structure 206.

In one embodiment, steps of forming the gate isolation structure 210 includes: forming a mask layer (not shown) on the first dielectric layer 209, where the mask layer exposes part of the first dummy gate structure 204 and the third dummy gate structure 206 located on the isolation layer 203 between the first region I and the second region II; forming a groove (not marked) by etching part of the first dummy gate structure 204 and part of the third dummy gate structure until the surface of the isolation layer 203 is exposed, by using the mask layer as a mask; and forming the gate isolation structure 210 in the groove.

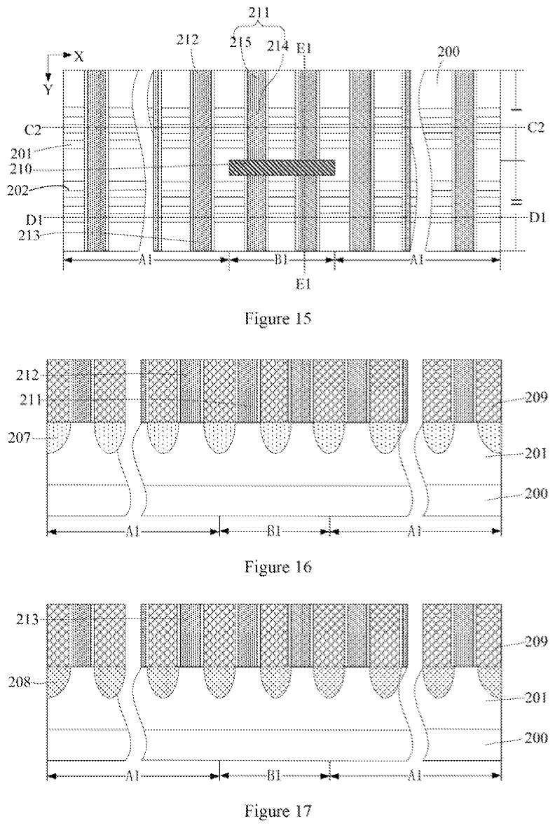

FIG. 15 is a top view of a semiconductor structure. The cutting direction of FIG. 16 is consistent with the cutting direction of FIG. 11, and the cutting direction of FIG. 17 is consistent with the cutting direction of FIG. 12. Referring to FIGS. 15-17, the process also includes: removing the first dummy gate structure 204, and forming a first gate opening (not marked) in the first dielectric layer 209; forming a first gate structure 211 in the first gate opening; removing the second dummy gate structure 205, and forming a second gate opening (not marked) in the first dielectric layer 209; forming the second gate structure 212 in the second gate opening; removing the third dummy gate structure 206, and forming a third gate opening (not marked) in the first dielectric layer 209; and forming the third gate structure 213 in the third gate opening.

In one embodiment, the first gate structure 211 includes a first portion 214 located on the surface of the first fin 201 and a second portion 215 located on the surface of the isolation layer 203.

In one embodiment, the first dummy gate dielectric layer and the first dummy gate layer of the first dummy gate structure 204, the second dummy gate dielectric layer and the second dummy gate layer of the second dummy gate structure 205, and the third dummy gate dielectric layer and the third dummy gate layer of the third dummy gate structure 206 are specifically removed.

In one embodiment, the first gate structure 211 includes a first gate dielectric layer (not shown) and a first gate layer (not marked) on the first gate dielectric layer. The second gate structure 212 includes a second gate dielectric layer (not shown) and a second gate layer (not shown) on the second gate dielectric layer. The third gate structure 213 includes a third gate dielectric layer (not shown) and a third gate layer (not shown) on the third gate dielectric layer.

In one embodiment, materials of the first gate dielectric layer, the second gate dielectric layer and the third gate dielectric layer include high-K dielectric materials.

Materials of the first gate layer, the second gate layer and the third gate layer include metal. The metal includes tungsten, aluminum, copper, titanium, silver, gold, lead or nickel. In one embodiment, the materials of the first gate layer, the second gate layer and the third gate layer are tungsten.

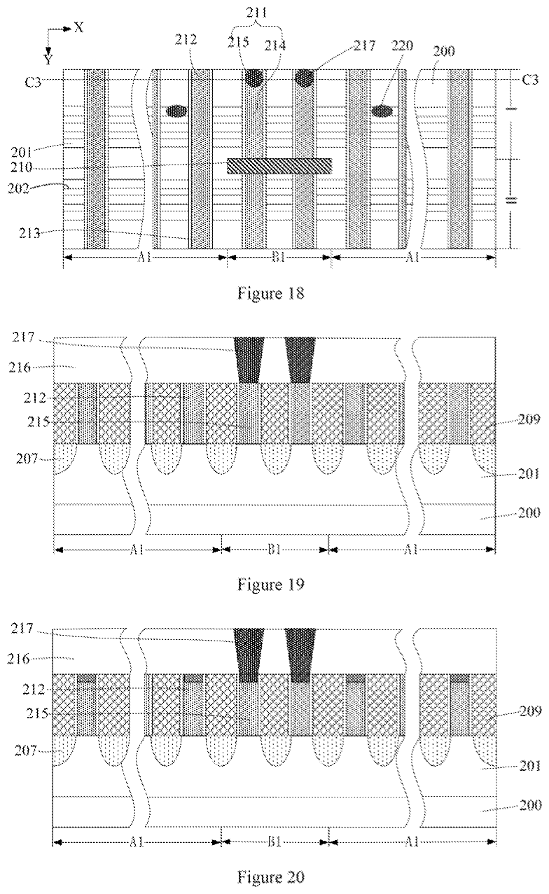

FIG. 18 is a top view of the semiconductor structure omitting the isolation layer, the first dielectric layer, and the second dielectric layer, and FIG. 19 is a cross-sectional structural schematic of FIG. 18 along the C3-C3 direction. Referring to FIGS. 18 and 19, a second dielectric layer 216 is formed on the first dielectric layer 209, the first gate structure 211, the second gate structure 212, and the third gate structure 213.

In one embodiment, the material of the second dielectric layer 216 is silicon oxide. In some other embodiments, the material of the second dielectric layer may be a low-K dielectric material (a low-K dielectric material refers to a dielectric material with a relative permittivity lower than 3.9) or an ultra-low-K dielectric material (an ultra-low-K dielectric material refers to a dielectric material with a relative permittivity lower than 2.5).

In one embodiment, after forming the second dielectric layer 216, a plurality of contact holes (not shown) separated from each other is formed in the second dielectric layer 216. Bottoms of the contact holes respectively expose the top surfaces of the second portions 215 of the first gate structures 211. A plug 217 is formed in each of the contact holes.

In one embodiment, the quantity of the plugs 217 is same as the quantity of the first gate structures 211. Each of the plugs 217 is respectively connected to the second portion 215 of the first gate structure 211.

In one embodiment, the top surface of the first gate structure 211 is flush with the top surface of the first dielectric layer 209, and the bottom surface of the plug 217 is flush with the top surface of the first dielectric layer 209.

The cutting directions of FIG. 20 and FIG. 19 are consistent. In some other embodiments, referring to FIG. 20, the top surface of the first gate structure 211 is lower than the top surface of the first dielectric layer 209. The top surface of the first gate structure 211 may have a cover layer, and the top surface of the cover layer is flush with the top surface of the first dielectric layer. Part of the plugs 217 may be located in the first dielectric layer 209.

In one embodiment, before forming the contact hole, the process also includes: etching back part of the first gate structure 211 until the top surface of the first gate structure 211 is lower than the top surface of the first dielectric layer 209.

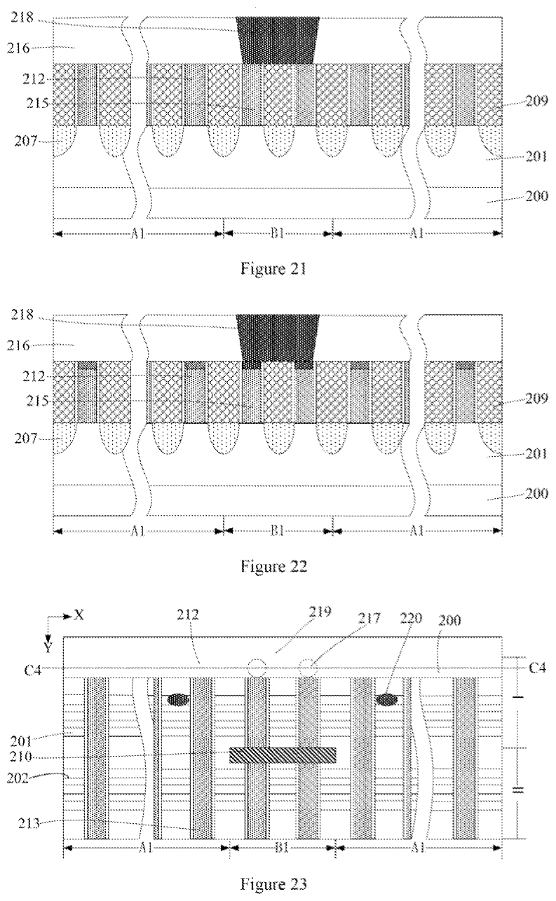

The cutting directions of FIG. 21 and FIG. 19 are consistent. In another embodiment, referring to FIG. 21, a contact hole (not marked) may be formed in the second dielectric layer 216. The bottom of the contact hole exposes the top surfaces of the second portions 215 of the adjacent plurality of first gate structures 211 and the top surface of the first dielectric layer 209 between the first gate structures 211. A plug 218 may be formed in the contact hole.

In one embodiment, the quantity of the plug 218 is one. The plug 218 is electrically connected to the second portions 215 of the plurality of first gate structures 211 simultaneously.

In one embodiment, the bottom surface of the plug 218 is flush with the top surface of the first dielectric layer 209.

The cutting directions of FIGS. 22 and 21 are consistent. In another embodiment, referring to FIG. 22, the bottom surface of the plug 218 may be lower than the top surface of the first dielectric layer 209. Before forming the contact hole, the first gate structure 211 may be etched back until the top surface of the first gate structure 211 is lower than the top surface of the first dielectric layer 209.

With continuous reference to FIG. 18, in one embodiment, the process also includes: forming a source/drain plug 220 on the first source/drain doped layer 207 on two sides of the first fin 201 on the first active region A1.

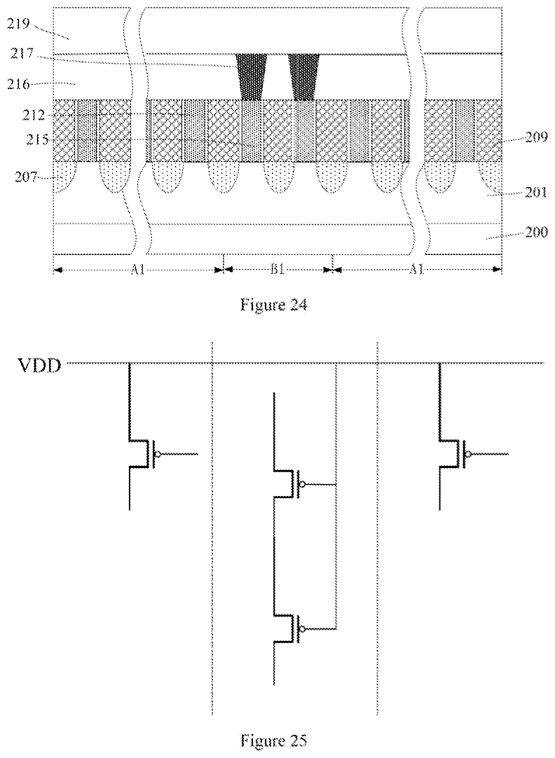

FIG. 23 is a top view of a semiconductor structure. FIG. 24 is a cross-sectional structural schematic of FIG. 23 along the C4-C4 direction. FIG. 25 is a simplified three-dimensional structure diagram of a semiconductor structure. Referring to FIG. 23-25, after the plug 217 is formed, an interconnection layer 219 is formed on the plug 217. The plug 217 and the interconnection layer 219 form a first electrical interconnection structure. The first electrical interconnection structure is electrically connected to the second portion 215 of the first gate structure 211.

In one embodiment, the process also includes: forming a first conductive layer (not shown) on the first source/drain doped layer 207, and forming a second conductive layer (not shown) on the second source/drain doped layer 208.

In one embodiment, the source/drain plug 220 and the interconnection layer 219 also form an interconnection structure.

FIG. 25 is a simplified circuit diagram of a semiconductor structure. Referring to FIG. 25, when the first region I is a PMOS region, the interconnection layer 219 is Vdd. The source/drain plug 220 is connected to the Vdd, and the plug 217 is connected to the Vdd.

When the first region I is an NMOS region, the interconnection layer 219 is Vss. The source/drain plug 220 is connected to the Vss, and the plug 217 is connected to the Vss.

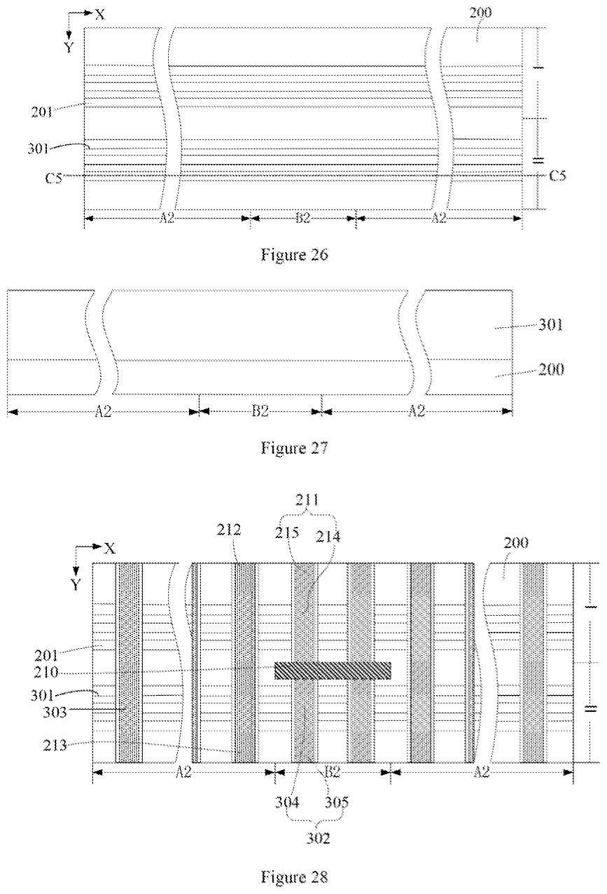

FIGS. 26-32 illustrate structural schematics corresponding to certain stages of another process of forming a semiconductor structure, consistent with the disclosed embodiments of the present disclosure.

FIG. 26 is a top view of the semiconductor structure, and FIG. 27 is a cross-sectional structure schematic of FIG. 26 along the direction C5-C5. Referring to FIGS. 26 and 27, in one embodiment, the second region II of the substrate 200 includes a plurality of second active regions A2 arranged along the first direction X and a second isolation area B2 located between adjacent second active regions A2.

A plurality of third fins 301 is formed in the second region II. The plurality of third fins 301 is parallel to the first direction X and are arranged along the second direction Y. The plurality of third fins 301 spans the second active region A2 and the second isolation region B2.

The formation method and material of the plurality of third fins 301 are same as the formation method and material of the plurality of first fins 201, and will not be repeated here. The isolation layer 203 also covers part of the sidewall surfaces of the third fins 301.

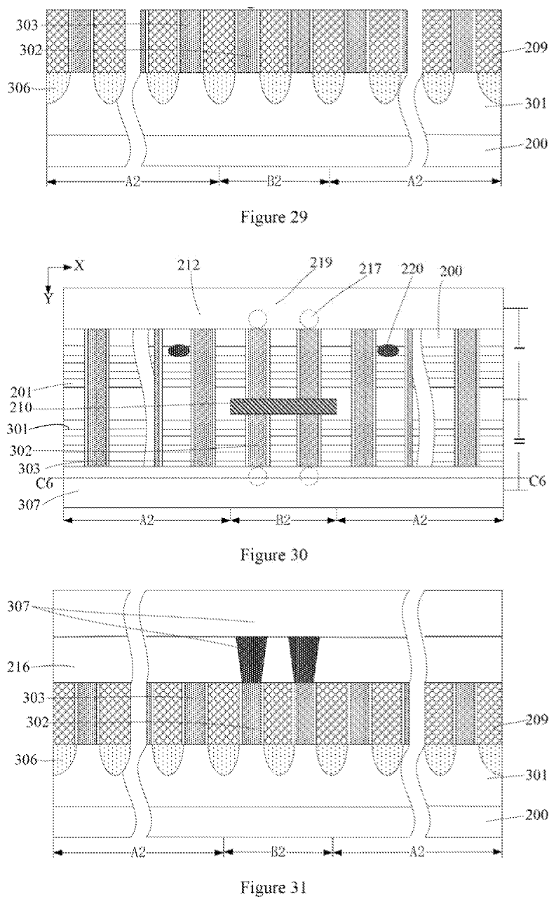

FIG. 28 is a top view of the semiconductor structure, and the cross-sectional directions of FIG. 29 and FIG. 28 are consistent. Referring to FIGS. 28 and 29, a plurality of fourth gate structures 302 is formed in the second isolation region B2. The plurality of fourth gate structure 302 spans the third fin 301. The fourth gate structure 302 and the first gate structure 211 are spaced apart from each other in the second direction Y. A plurality of fifth gate structures 303 is formed on the second active region A2. The plurality of fifth gate structure 303 spans the third fins 301 on the second active region A2, and the fifth gate structure 303 is connected to the second gate structure 212.

The fourth gate structure 302 includes a third portion 304 located on the surface of the third fin 301 and a fourth portion 305 located on the surface of the isolation layer 203.

In one embodiment, the methods and materials for forming the fourth gate structure 302 and the fifth gate structure 303 are same as the methods and materials for forming the first gate structure 211 and the third gate structure 213, and will not be repeated here.

Before forming the fourth gate structure 302 and the fifth gate structure 303, the process also includes: forming a third source/drain doped layer 306 in the third fins on two sides of the fourth gate structure and the fifth gate structure. The third source/drain doped layer 306 contains third source/drain ions inside.

The conductivity type of the third source/drain ions is different from the conductivity type of the first source/drain ions. The first source/drain ions may include N-type ions or P-type ions, and the third source/drain ions may include P-type ions or N-type ions.

FIG. 29 is a top view of a semiconductor structure, and FIG. 31 is a cross-sectional structure schematic of FIG. 30 along the direction C6-C6. Referring to FIGS. 30 and 31, a second dielectric layer 216 may be formed on the first dielectric layer 209. A second electrical interconnection structure 307 may be formed in the second dielectric layer 216. The second electrical interconnection structure 307 is electrically connected to the fourth portion 305 of the fourth gate structure 302.

In one embodiment, the formation method and structure of the second electrical interconnection structure 307 are same as the formation method and structure of the first electrical interconnection structure, and will not be repeated here.

In one embodiment, the process also includes forming a third conductive layer (not shown) on the third source/drain doped layer 306.

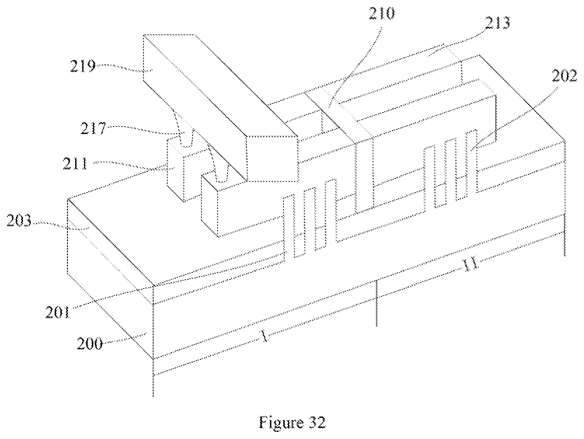

FIG. 32 is a simplified structural schematic of a semiconductor structure. Referring to FIGS. 23, 24 and 32, the present disclosure also provides a semiconductor structure. The semiconductor structure includes: a substrate 200, where the substrate 200 includes a first region I, and the first region I includes a plurality of first active regions A1 arranged along the first direction X and a first isolation region B1 located between adjacent first active regions A1; a plurality of first fins 201 located on the substrate 200, where the plurality of first fins 201 is parallel to the first direction X and is arranged along a second direction Y, the second direction Y is perpendicular to the first direction X, and the first fins 201 span the adjacent first active region A1 and the first isolation region B1 between the first active region A1; a plurality of first gate structures 211 located on the first isolation region B1, where the first gate structures 211 span the first fin 201 along the second direction Y; and a plurality of first electrical interconnection structures, where the plurality of first electrical interconnection structures is electrically connected to the first gate structures 211.

In one embodiment, the semiconductor structure also includes: an isolation layer 203 on the substrate 200, where the isolation layer 203 covers part of the sidewalls of the first fins 201, and the top surface of the isolation layer 203 is lower than the top surfaces of the first fins 201. The first gate structure 211 includes a first portion 214 located on the surface of the first fin 201 and a second portion 215 located on the surface of the isolation layer 203. The first electrical interconnection structure is electrically connected to the second portion 215.

In one embodiment, the semiconductor structure also includes: a second gate structure 212 located on the first active region A1. The second gate structure 212 spans the first fins 201 along the second direction Y.

In one embodiment, the semiconductor structure also includes a first dielectric layer 209 located on the substrate 200. The first dielectric layer 209 covers the sidewall of the first gate structure 211.

In one embodiment, the first electrical interconnection structure includes a plurality of plugs 217 located on the top surface of the second portion 215 of the first gate structure 211, and an interconnection layer 219 located on the plurality of plugs 217. The plurality of plugs 217 is separated from each other.

In one embodiment, the top surface of the first gate structure 211 is flush with the top surface of the first dielectric layer 209.

Referring to FIG. 20, in another embodiment, a top surface of the first gate structure 211 is lower than a top surface of the first dielectric layer 209, and a part of the plugs 217 is located in the first dielectric layer 209.

In one embodiment, the semiconductor structure also includes a second dielectric layer 216 located on the first dielectric layer 209. The first electrical interconnection structure is located in the second dielectric layer 216.

Referring to FIG. 21, in another embodiment, the first electrical interconnection structure includes a plug 218 located on the top surface of the adjacent first gate structures 211 and an interconnection layer 219 located on the plug 218. The plug 218 is also located on the surface of the first dielectric layer 209 between adjacent first gate structures 211.

In one embodiment, the top surface of the first gate structure 211 is flush with the top surface of the first dielectric layer 209.

Referring to FIG. 22, in another embodiment, the top surface of the first gate structure 211 is lower than the top surface of the first dielectric layer 209, and a part of the plugs 218 is also located in the first dielectric layer 209.

In one embodiment, the substrate 200 also includes a second region II.

In one embodiment, the second region II does not include an isolation region. In another embodiment, the second region II includes a plurality of second active regions arranged along the first direction X and a second isolation region located between adjacent second active regions.

In one embodiment, the semiconductor structure also include: a plurality of second fins 202 located on the second region II, where the plurality of second fins 202 is parallel to the first direction X and arranged along the second direction Y; and a plurality of third gate structures 213 located on the second region II, where the plurality of third gate structure 213 spans the second fins 202, and a part of the third gate structures 213 is connected to the second gate structure 212.

A gate isolation structure 210 may be disposed between part of the third gate structures 213 and the first gate structures 211. The gate isolation structure 210 is located on the isolation layer 203 between the first region I and the second region II.

In one embodiment, the semiconductor structure also includes: a first source/drain doped layer 207 in the first fin 201 located on two sides of each of the first gate structures 211 and on two sides of the second gate structure 212, where the first source/drain doped layer 207 contains first source/drain ions; and a second source/drain doped layer 208 in the second fin 202 located on two sides of each third gate structure 213, where the second source/drain doped layer 208 contains second source/drain ions.

In one embodiment, the conductivity types of the first source/drain ions and the second source/drain ions are different. The first source/drain ions may include N-type ions or P-type ions; and the second source/drain ions may include P-type ions or N-type ions.

In one embodiment, the semiconductor structure also includes: a first conductive layer (not shown) on the first source/drain doped layer 207 and a second conductive layer (not shown) on the second source/drain doped layer 208.

In another embodiment, referring to FIGS. 29 and 30, the second region II includes a plurality of second active regions A2 arranged along the first direction X and a second isolation region B2 located between adjacent second active regions A2.

A plurality of third fins 301 may be formed on the second region II. The plurality of third fins 301 is parallel to the first direction X and is arranged along the second direction Y. The third fins 301 span the adjacent second active region A2 and the second isolation region B2 between the second active regions A2. The semiconductor structure also includes a plurality of fourth gate structures 302 located on the second isolation region B2, where the fourth gate structures 302 span the third fin 301 along the second direction Y, and the fourth gate structure 302 is spaced apart from the first gate structure 211 in the second direction Y; and a plurality of second electrical interconnection structures 307, where the second electrical interconnection structures 307 are electrically connected to the fourth gate structure 302.

In one embodiment, the structure of the second electrical interconnection structure is same as the structure of the first electrical interconnection structure, and will not be repeated here.

In one embodiment, the fourth gate structure 302 includes a third portion 304 located on the surface of the third fin 301 and a fourth portion 305 located on the surface of the isolation layer 203. The second electrical interconnection structure is electrically connected to the fourth portion 305.

In one embodiment, the semiconductor structure also includes a fifth gate structure 303 located on the second active region A2. The fifth gate structure 303 spans the third fins 301 along the second direction Y, and the fifth gate structure 303 is connected to the second gate structure 212.

In one embodiment, the semiconductor structure also includes a third source/drain doped layer 306 in the third fins located on two sides of each of the fourth gate structures 302 and on two sides of the fifth gate structure 303. The third source/drain doped layer 306 contains third source/drain ions.

The conductivity type of the first source/drain ions is different from the conductivity type of the third source/drain ion. The first source/drain ions may include N-type ions or P-type ions; the third source/drain ions may include P-type ions or N-type ions.

In one embodiment, the semiconductor structure also includes a third conductive layer (not shown) located on the third source/drain doped layer 306.

The present disclosure also provides an operation method of a semiconductor structure, including providing a semiconductor structure. The semiconductor structure includes: a substrate 200, where the substrate 200 includes a first region I, and the first region I includes a plurality of first active regions A1 arranged along the first direction X and a first isolation region B1 located between adjacent first active regions A1; a plurality of first fins 201 located on the substrate 200, where the plurality of first fins 201 is parallel to the first direction X and is arranged along a second direction Y, the second direction Y is perpendicular to the first direction X, and the first fins 201 span the adjacent first active region A1 and the first isolation region B1 between the first active region A1; a plurality of first gate structures 211 located on the first isolation region B1, where the first gate structures 211 span the first fin 201 along the second direction Y; and a plurality of first electrical interconnection structures, where the plurality of first electrical interconnection structures is electrically connected to the first gate structures 211. The operation method includes applying a voltage to the first electrical interconnection structure to turn off the channel region at the bottom of the first gate structure 211.

The semiconductor structure also includes a first source/drain doped layer 207 in the first fin 201 located on two sides of each of the first gate structures 211, where the first source/drain doped layer 207 contains first source/drain ions. The operation method also includes: when the first source/drain ions are N-type ions, applying a negative voltage to the first electrical interconnection structure; and when the first source/drain ions are P-type ions, applying a positive voltage to the first electrical interconnection structure.

An off signal may be provided to the first gate structure 211 by applying a voltage to the first electrical interconnection structure, such that the channel region at the bottom of the first gate structure 211 is in an off state, making the first gate structure 211 ineffective. Accordingly, the electrical isolation of the first active regions A1 on two sides of the first isolation region B1 may be realized. On the one hand, there is no need to remove the first gate structure 211 to form an isolation structure, and the integration level of the semiconductor structure may be improved. On the other hand, the first fin 201 does not need to be cut in the first isolation region B1. Accordingly, the layout dependence effect caused by the cut-off structure of the first fin 201 may be avoided, and the performance of the semiconductor structure may be improved.

In another embodiment, the semiconductor structure also includes: a second region II, where the second region II includes a plurality of second active regions A2 arranged along the first direction X and a second isolation region B2 located between adjacent second active regions A2; a plurality of fourth gate structures 302 located on the second isolation region B2, where the fourth gate structures 302 span the third fin 301 along the second direction Y, and the fourth gate structure 302 is spaced apart from the first gate structure 211 in the second direction Y; and a plurality of second electrical interconnection structures 307, where the second electrical interconnection structures 307 are electrically connected to the fourth gate structure 302. The operation method also includes applying a voltage to the second electrical interconnection structure 307 to turn off the channel region at the bottom of the fourth gate structure 302.

The semiconductor structure also includes: a third source/drain doped layer 306 in the third fins located on two sides of each of the fourth gate structures 302 and on two sides of the fifth gate structure 303. The third source/drain doped layer 306 contains third source/drain ions. The conductivity type of the third source/drain ions is different from the conductivity type of the first source/drain ions. The operation method includes: when the third source/drain ions are N-type ions, applying a negative voltage to the second electrical interconnection structure; and when the third source/drain ions are P-type ions, applying a positive pressure to the second electrical interconnection structure.

Although the present disclosure has been disclosed above, the present disclosure may not be limited thereto. Changes and modifications may be made by those skilled in the art without departing from the spirit and scope of the present disclosure. Therefore, the scope of the present disclosure should be determined by the scope defined by appended claims.

1. A semiconductor structure, comprising:
a substrate, wherein the substrate includes a first region, and the first region includes a plurality of first active regions arranged along a first direction and a first isolation region located between adjacent first active regions of the plurality of first active regions;
a plurality of first fins located over the substrate, wherein the plurality of first fins extends in parallel to the first direction and is arranged along a second direction, the second direction is perpendicular to the first direction, and the plurality of first fins spans the adjacent first active regions and the first isolation region between the adjacent first active regions;
a plurality of first gate structures located over the first isolation region, wherein the plurality of first gate structures spans the plurality of first fins along the second direction; and
a plurality of first electrical interconnection structures, wherein the plurality of first electrical interconnection structures is electrically connected to the plurality of first gate structures.

2. The semiconductor structure according to claim 1, further comprising an isolation layer over the substrate, wherein:
the isolation layer covers a part of sidewalls of the plurality of first fins, a top surface of the isolation layer is lower than a top surface of the plurality of first fins, a first gate structure of the plurality of first gate structures includes a first portion located on a surface of a first fin of the plurality of first fins and a second portion located on a surface of the isolation layer, and a first electrical interconnection structure of the plurality of first electrical interconnection structures is electrically connected to the second portion.

3. The semiconductor structure according to claim 1, further comprising:
a first dielectric layer located over the substrate, wherein the first dielectric layer covers a sidewall of a first gate structure of the plurality of first gate structures.

4. The semiconductor structure according to claim 3, wherein:
a first electrical interconnection structure of the plurality of first electrical interconnection structures includes a plurality of plugs located on a top surface of a second portion of the first gate structure, and an interconnection layer located over the plurality of plugs;
the plurality of plugs is separated from each other; and
a top surface of the first gate structure is lower than a top surface of the first dielectric layer, and a part of the plurality of plugs is located in the first dielectric layer.

5. (canceled)

6. The semiconductor structure according to claim 3, wherein:
a first electrical interconnection structure of the plurality of first electrical interconnection structures includes plugs located over a top surface of adjacent first gate structures of the plurality of first gate structures and an interconnection layer located over the plugs;
the plugs are also located over a surface of the first dielectric layer between the adjacent first gate structures; and
a top surface of the first gate structure is lower than a top surface of the first dielectric layer, and a part of the plugs is also located in the first dielectric layer.

7. (canceled)

8. The semiconductor structure according to claim 1, further comprising:
a second gate structure located over first active regions of the plurality of the first active regions, wherein the second gate structure spans the plurality of first fins along the second direction.

9. The semiconductor structure according to claim 8, wherein the substrate further includes:
a second region;
a plurality of second fins located over the second region, wherein the plurality of second fins extends in parallel to the first direction and is arranged along the second direction; and
a plurality of third gate structures located over the second region, wherein the plurality of third gate structure spans the plurality of second fins, and a part of the plurality of third gate structures is connected to the second gate structure.

10. The semiconductor structure according to claim 8, wherein the substrate further includes a second region, wherein the second region includes:
a plurality of second active regions arranged along the first direction and a second isolation region located between adjacent second active regions of the plurality of second active regions;
a plurality of third fins on the second region, wherein the plurality of third fins extends in parallel to the first direction and is arranged along the second direction, and a third fin of the plurality of third fins spans the adjacent second active regions and the second isolation region between the adjacent second active regions;
a plurality of fourth gate structures located over the second isolation region, wherein the plurality of fourth gate structures spans the third fin along the second direction, and the plurality of fourth gate structure is spaced apart from a first gate structure of the plurality of first gate structures in the second direction;
a plurality of second electrical interconnection structures, wherein the plurality of second electrical interconnection structures is electrically connected to a fourth gate structures of the plurality of fourth gate structures; and
a fifth gate structure located over a second active region of the plurality of second active regions, wherein the fifth gate structure spans the third fin along the second direction, and the fifth gate structure is connected to the second gate structure.

11. (canceled)

12. The semiconductor structure according to claim 9, further comprising:
a first source/drain doped layer in a first fin of the plurality of first fins located on two sides of each of the plurality of first gate structures and on two sides of the second gate structure, wherein the first source/drain doped layer contains first source/drain ions; and
a second source/drain doped layer in a second fin of the plurality of second fins located on two sides of each of the plurality of third gate structures, wherein the second source/drain doped layer contains second source/drain ions, wherein
conductivity types of the first source/drain ions and the second source/drain ions are different;
the first source/drain ions include N-type ions or P-type ions; and
the second source/drain ions include P-type ions or N-type ions.

13. (canceled)

14. The semiconductor structure according to claim 12, further comprising:
a first conductive layer over the first source/drain doped layer and a second conductive layer over the second source/drain doped layer.

15. The semiconductor structure according to claim 10, further comprising:
a first source/drain doped layer in a first fin of the plurality of first fins located on two sides of each of the plurality of first gate structures and on two sides of the second gate structure, wherein the first source/drain doped layer contains first source/drain ions; and
a third source/drain doped layer in the third fin located on two sides of each of the plurality of fourth gate structures and on two sides of the fifth gate structure, wherein the third source/drain doped layer contains third source/drain ions, wherein
conductivity types of the first source/drain ions and the third source/drain ions are different;
the first source/drain ions include N-type ions or P-type ions;
the third source/drain ions include P-type ions or N-type ions; and
a first conductive layer is located on the first source/drain doped layer and a third conductive layer is located on the third source/drain doped layer.

16. (canceled)

17. (canceled)

18. A method for forming a semiconductor structure, comprising:
providing a substrate, wherein the substrate includes a first region, the first region includes a plurality of first active regions arranged along a first direction and a first isolation region located between adjacent first active regions of the plurality of first active regions;
forming a plurality of first fins over the first region, wherein the plurality of first fins extends in parallel to the first direction and is arranged along a second direction, the second direction is perpendicular to the first direction, and the plurality of first fins spans the adjacent first active regions and the first isolation region between the adjacent first active regions;
forming a plurality of first gate structures over the first isolation region, wherein the plurality of first gate structures spans the plurality of first fins along the second direction; and
forming a plurality of first electrical interconnection structures, wherein the plurality of first electrical interconnection structures is electrically connected to the plurality of first gate structures.

19. The method according to claim 18, after forming the plurality of first fins, further comprising:
forming an isolation layer over the substrate, wherein the isolation layer covers a part of sidewalls of the plurality of first fins, and a top surface of the isolation layer is lower than a top surface of the plurality of first fins.

20. The method according to claim 18, after forming the plurality of first fins and before forming the plurality of first gate structures, further comprising:
forming a plurality of first dummy gate structures over the first isolation region, wherein the plurality of first dummy gate structures spans the plurality of first fins; and
forming a first dielectric layer over the substrate, wherein the first dielectric layer covers sidewalls of the plurality of first dummy gate structure, and exposes a top surface of the plurality of first dummy gate structures.

21. The method according to claim 20, wherein a process of forming the plurality of first gate structures includes:
removing the plurality of first dummy gate structures to form a plurality of first gate openings in the first dielectric layer; and
forming the plurality of first gate structures in the plurality of first gate openings.

22. The method according to claim 21, after forming the plurality of first gate structures, further comprising:
forming a second dielectric layer on the first dielectric layer, wherein the plurality of first electrical interconnection structures is located in the second dielectric layer.

23. The method according to claim 22, wherein a process of forming the plurality of first electrical interconnection structures includes:
etching back a part of the plurality of first gate structures until a top surface of the plurality of first gate structures is lower than a top surface of the first dielectric layer;
forming a plurality of contact holes separated from each other in the second dielectric layer, wherein bottoms of the plurality of contact holes respectively expose top surfaces of the plurality of first gate structures;
forming a plug in each of the plurality of contact holes; and
forming an interconnection layer over the plug.

24. (canceled)

25. The method according to claim 22, wherein a process of forming the plurality of first electrical interconnection structures includes:
etching back a part of the plurality of first gate structures until a top surface of the plurality of first gate structures is lower than a top surface of the first dielectric layer;
forming a contact hole in the second dielectric layer, wherein a bottom of the contact hole exposes a plurality of adjacent first gate structures of the plurality of first gate structures and a top surface of the first dielectric layer between the plurality of first gate structures;
forming a plug in the contact hole; and
forming an interconnection layer over the plug.

26. (canceled)

27. An operation method of a semiconductor structure, comprising:
providing a semiconductor structure, wherein the semiconductor structure includes:
a substrate, wherein the substrate includes a first region, and the first region includes a plurality of first active regions arranged along a first direction and a first isolation region located between adjacent first active regions of the plurality of first active regions;
a plurality of first fins located over the substrate, wherein the plurality of first fins extends in parallel to the first direction and is arranged along a second direction, the second direction is perpendicular to the first direction, and the plurality of first fins spans the adjacent first active regions and the first isolation region between the adjacent first active regions;
a plurality of first gate structures located over the first isolation region, wherein the plurality of first gate structures spans the plurality of first fins along the second direction; and
a plurality of first electrical interconnection structures, wherein the plurality of first electrical interconnection structures is electrically connected to the plurality of first gate structures; and
applying a voltage to the plurality of first electrical interconnection structures to turn off a channel region at a bottom of the plurality of first gate structure.

28. The operation method according to claim 27, wherein:
the semiconductor structure further includes a first source/drain doped layer in a first fin of the plurality of first fins located on two sides of each of the plurality of first gate structures, wherein the first source/drain doped layer contains first source/drain ions; and
the operation method further includes, when the first source/drain ions are N-type ions, applying a negative voltage to the plurality of first electrical interconnection structures, and when the first source/drain ions are P-type ions, applying a positive voltage to the plurality of first electrical interconnection structures.
